(19) United States
(12) Patent Application Publication
(10) Pub. No.: US 2005/0068831 A1
(43) Pub. Date: Mar. 31, 2005

(54) Method and apparatus to employ a memory module information file

(76) Inventor: Brian P. Johnson, Folsom, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/676,886

(22) Filed: Sep. 30, 2003

(51) Int. Cl. G11C 7/00

(52) U.S. Cl. 365/222

(57) ABSTRACT

A method and apparatus to employ a memory module information file is described. In one embodiment, information related to identifying characteristics of a memory module of a system, stored on a non-volatile unit of memory (e.g., an SPD), is used to access a separate file providing additional information about the memory module. The information accessed from the separate file is then used to further optimize a performance threshold of the memory module.

### FIELD OF INVENTION

The field of invention relates generally to computing system optimization; and, more specifically, to a method and apparatus to employ a memory module information file.

### BACKGROUND

Computing systems include a system memory. A system memory is generally viewed as a memory resource: a) from which different components of the computing system may desire to obtain data from; and, 2) to which different components of the computing system may desire to store data within. FIG. 1 shows a simple diagram of a portion of a computing system that includes a system memory 106 and a memory controller 101. Because different computing system components often desire to invoke the resources of the system memory quasi-simultaneously (e.g., a plurality of different computing system components “suddenly” decide to invoke the system memory resources within a narrow region of time), the memory controller 101 is responsible for managing the order and the timing in which the different components are serviced by the system memory 106.

FIG. 1 is drawn to provide some insight into a typical application. Note that the memory controller 101 is configured to manage the various system memory invocations that are generated by: 1) one or more processors (e.g., through a processor front side bus 108); 2) a graphics controller (e.g., through graphics controller interface 109); and, 3) various peripheral components of the overall computing system (e.g., through system bus interface 110 (e.g., a Peripheral Components Interface (PCI) bus interface). The system memory 106 may be constructed from a number of different memory semiconductor chips and may be simplistically viewed as having an address bus 104 and a data bus 105. Specific memory cells are accessed by presenting corresponding address values on the address bus 104. The data value being read from or written to a specific memory cell appears on data bus 105.

Memory controllers may be equipped with an ability to regulate the utilization or usage that is applied to the system memory 106. For example, as observed in FIG. 1, memory controller 101 includes a threshold register 102 that stores a threshold value. The threshold value is used to control the rate at which the system memory 106 is involved with various activities (e.g., various accesses such as reads, writes, activations, etc.); and, by so doing, controls the usage or utilization that is applied to the system memory 106. The memory controller 101, in response to the threshold value, is designed to pace the rate at which activities are applied to the system memory 106 so that the usage applied to the system memory 106 does not over-utilize the system memory 106.

As a simplistic example, FIG. 2 shows some examples of how different read and write rates may be applied to a system memory in response to different threshold values. A first depiction 201 shows a maximum rate at which reads and writes (signified by “R”s and “W”s, respectively) may be applied to a system memory according to a first threshold value. A second depiction 202 shows a maximum rate at which reads and writes may be applied to a system memory according to a second threshold value. As the first depiction 201 clearly shows more reads and writes (over approximately the same time period) as compared to the second depiction 202, the first threshold allows for a higher maximum rate of reads and writes than the second threshold.

The threshold value that is used by the computing system (or information from which the threshold value can be computed) may be stored in a non volatile memory region such as the Serial Presence Detect (SPD) memory region 114 of the computing system, which stores information that describes and/or characterizes the system memory 106.

For example, during the boot sequence, the system Basic Input Output System (BIOS) 107 may read data from the SPD. The BIOS may then use an algorithm and a lookup table to calculate the maximum amount of traffic to issue to the memory to prevent the memory components from overheating (i.e., exceeding the specified junction temperatures).

However, today, the algorithm typically assumes a single set of values for the power (IDD current) used by the memory components. This value is typically the worst case IDD value across all of the memory suppliers in the industry. The worst case IDD value may require significant throttling of cycles to the memory to prevent overheating. Memory vendors, however, who can deliver significantly lower power memory components do not have a way to provide the information to the memory controller.

### FIGURES

One or more embodiments are illustrated by way of example, and not limitation, in the Figures of the accompanying drawings in which

FIG. 1 shows a portion of a prior art computing system;

FIG. 2 shows examples of different rates at which activity may be applied to a computing system's system memory;

FIG. 3 is a flow diagram describing the processes of employing a memory module information file in accordance with one embodiment; and

FIG. 4 illustrates a system to access the memory module information file, in accordance with one embodiment.

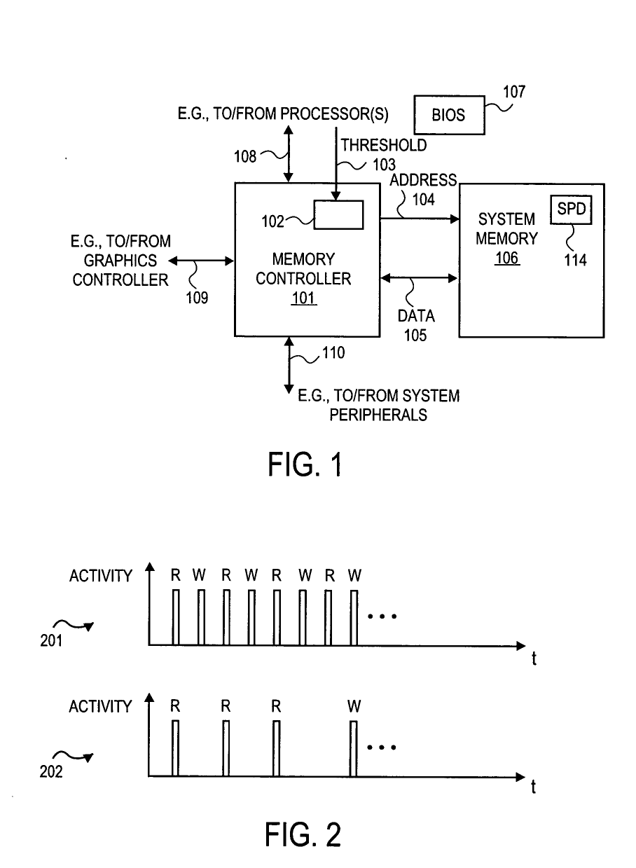

### DETAILED DESCRIPTION

A method and apparatus to employ a memory module information file is described. In one embodiment, information related to identifying characteristics of a memory module of a system, stored on a non-volatile unit of memory (e.g., an SPD), are used to access a separate file providing additional information about the memory module. The information accessed from the separate file is then used to further optimize a performance of the memory module.

In the following description, numerous specific details are set forth. However, it is understood that embodiments may be practiced without these specific details. In other instances, well-known circuits, structures and techniques have not been shown in detail in order not to obscure the understanding of this description.

Reference throughout this specification to “one embodiment” or “an embodiment” indicate that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

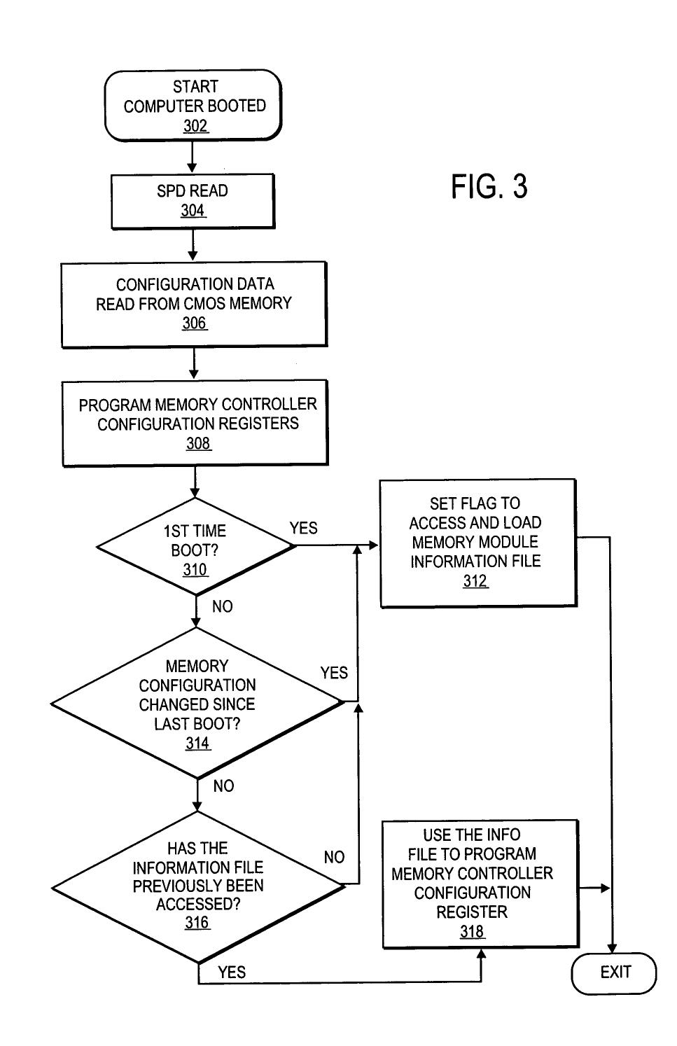

FIG. 3 is a flow diagram describing the process of accessing and using information from the memory module file stored separate from the SPD to optimize performance of memory module unit. In process 302, the computer system is booted. In process 304, the SPD of the memory module provided in the system is read by the BIOS. In one embodiment, the SPD will provide a memory module model number and/or the memory module manufacturer. In alternative embodiments, the SPD may include additional information related to the memory module provided on the system. Also, a non-volatile memory unit other than the SPD may be accessed to obtain the same or similar information.

In 306, in one embodiment, system/memory configuration data is read from a CMOS memory battery backed unit. As described herein, in alternative embodiments, memory devices other than a CMOS memory may store the system/memory configuration data to be accessed.

In process 308, the system/memory configuration data from the CMOS is loaded into the memory controller configuration registers, which is then used by the memory controller as an initial basis to control the performance of the memory module unit. For example, the memory configuration data may be used to control the throttling rate of read/write memory transactions issued to the memory module unit.

In process 310, the BIOS determines if the present booting of the computer system is an initial booting of the computer system. For example, in one embodiment, the first time the computer is booted the contents of the Real Time Clock memory are not valid.

In one embodiment, if the BIOS determines the present booting of the computer system is the initial booting of the computer system, in process 312, the BIOS sets a flag to have the memory module information file, which contains additional information identifying characteristics of the actual memory modules in the system, accessed and loaded to be used by the memory controller to further optimize the transactions of the memory unit. The BIOS would then proceed with completing the booting and the Power on Self Test (POST).

In one embodiment, the flag may be set in an area to be accessed by the operating system (OS), which would access and load the memory module information file. Alternatively, an application separate from the OS can be run to determine if the flag has been set, and access and load the file accordingly. In an alternative embodiment, a display message may be prompted for a user of the computer system, requesting the memory module information file be accessed and loaded.

In one embodiment, the information accessed from the SPD (e.g., the model number and/or vendor of the memory module) is used to search and identify the proper memory module information file considering the type of memory module installed in the system. In one embodiment, the information accessed from the SPD may be used as a key to a table storing a set of memory module information files. In particular, a hash of the data from the SPD may be used to identify a field in the table, which provides an address to the desired information file that may then be loaded.

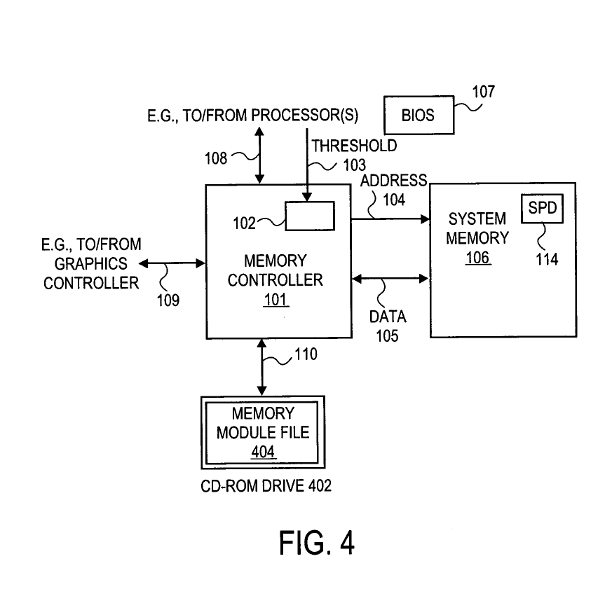

In one embodiment, the memory module information file could be stored and accessed from a variety of locations. For example, the information file may be stored on a floppy disk, a CD-ROM, or on the hard-disk drive, where the information file could be part of the operating system or some other application or file stored on the hard disk drive. For example, as illustrated in FIG. 4, the memory module information file 404 could be stored on a CD-ROM accessible via the CD-ROM drive 402. Alternatively, the information file could be downloaded from a separate computer across a network connection, such as down loading the information file from the Internet from a World Wide Web site.

The information from the memory module information file includes additional information related to the memory modules installed in the system. For example, in one embodiment, the information from the file may include data related to current and power specification of the memory module installed in the system. The information may also include detailed core timing requirements at different operation frequencies, multiple speeds of operation, memory trace length information, package type information, detailed refresh intervals vs. junction temperature tables, detailed derating information for applications that want to run the memory modules at lower voltage to save power (e.g., mobile applications). Other information and parameters may also be provided via the memory module information files, including any other mechanical or electrical specification of the memory module that can impact the way the memory controller accesses the memory module.

Once the memory module driver information file has been accessed, in one embodiment, the file is parsed into selected data and stored on the CMOS memory. Thereafter, the BIOS may use the parsed data to program the configuration registers of the memory controller or chipset to further optimize the memory transactions to the memory module. In one embodiment, the BIOS may use an algorithm in processing the data from the information files in addition to other system factors, such as the system's current ambient temperature and/or the system's thermal cooling capabilities, to produce memory configuration data for programming the memory controller.

If the BIOS, however, has determined that the present booting of the computer system is not the initial booting of the computer system, in process 314, the BIOS determines if the memory configuration data as provided in the CMOS memory has been changed since a most recent booting of the system. For example, if the memory modules of the system have been changed since a most recent booting of the system, the memory configuration data as provided in the CMOS memory would indicate such. In one embodiment, the CMOS memory may include a field that may indicate whether the memory configuration data is valid.

If the BIOS determines the memory configuration data as provided in the CMOS memory has been changed since a most recent booting of the system, in process 312, the flag is set to have the memory module information file accessed and loaded to be used by the memory controller to further optimize the transactions of the memory unit.

If the BIOS, however, has determines that the memory configuration data as provided in the CMOS memory has not been changed since a most recent booting of the system, in process 316, the BIOS determines if the memory configuration data as provided in the CMOS memory is valid. In one embodiment, the memory configuration data is considered valid if the memory module driver information file has previously been obtained to optimize the throttling of the memory module. In one embodiment, a field within the CMOS memory would indicate such.

If the BIOS determines the memory configuration data as provided in the CMOS memory is not valid, in process 312, the flag is set to have the memory module driver information file accessed and loaded to be used by the memory controller to further optimize the transactions of the memory unit.

If the BIOS, however, determines the memory configuration data as provided in the CMOS memory is valid, in process 318, the BIOS can use the additional information provided by the memory module information file (that has been parsed and stored in the CMOS memory) to program the configuration registers of the memory controller to further optimize the transactions of the memory unit.

In alternative embodiments, additional processes may be performed to determine whether the memory module driver information file is to be obtained to optimize the throttling of the memory module. Likewise, less than all of the processes discussed above may be performed to determine whether the memory module driver information file is to be obtained to optimize the throttling of the memory module. In addition, in alternative embodiment, an application or operating system, rather than the BIOS, may perform the processes discussed above to determine whether the memory module driver information file is to be obtained to optimize the throttling of the memory module.

In addition, the above described processes may be used with a chipset, a discrete memory controller, a memory controller integrated on a chipset, a memory controller integrated on a central processing unit (CPU), and a memory controller integrated with other system peripherals and/or controllers, or some other combination of integration with the above identified components.

Furthermore, the above described processes can be used on any type of memory module, include Dynamic Random Access Memory (DRAM), Synchronous Random Access Memory (SRAM), Flash Memory, and other types of memory. The processes described above could also support soldered down memory. For example, in the case of a system manufacturer using several memory suppliers in their line and had a mechanism similar to SPD, the system could tell which memory components are soldered down/installed to the board. Alternatively, a different BIOS code could be provided for each board with a different memory type soldered down/installed.

The processes described above can be stored in the memory of a computer system as a set of instructions to be executed. In addition, the instructions to perform the processes described above could alternatively be stored on other forms of machine-readable media, including magnetic and optical disks. For example, the processes described could be stored on machine-readable media, such as magnetic disks or optical disks, which are accessible via a disk drive (or computer-readable medium drive). For example, as illustrated in the system of FIG. 4, where the memory module information file is accessed via the CD-ROM drive. Further, the instructions can be downloaded into a computing device over a data network in a form of compiled and linked version.

Alternatively, the logic to perform the processes as discussed above, could be implemented in additional computer and/or machine readable media, such as discrete hardware components as large-scale integrated circuits (LSI's), application-specific integrated circuits (ASIC's), firmware such as electrically erasable programmable read-only memory (EEPROM's); and electrical, optical, acoustical and other forms of propagated signals (e.g., carrier waves, infrared signals, digital signals, etc.); etc.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. A method comprising:
Accessing a first unit of data from a Serial Presence Detect (SPD) device of a memory unit; and
Accessing, via the first unit of data, a second unit of data stored separately from the first unit of data.

2. The method of claim 1, wherein the second unit of data is accessed from one of a group comprising of a hard disk drive, a floppy disc, a CD-ROM, and a separate computer interconnected via a network.

3. The method of claim 2, wherein the second unit of data is a memory module information file.

4. The method of claim 3, further including storing at least a subunit of the memory module information file in a register of a memory controller, the subunit of the information file to be used to throttle memory cycles.

5. The method of claim 4, wherein the memory module information file includes information related to at least one of a group comprising of multiple speeds of operation for the memory unit, multiple operating frequencies of the memory unit, memory trace length information, and package type information.

6. The method of claim 5, wherein the second unit of data is accessed in response to an initial booting of a computer system.

7. The method of claim 5, wherein the second unit of data is accessed in response to a change in the memory controller configuration register.

8. The method of claim 5, wherein the second unit of data is accessed in response to an indication that the memory module information file has not previously been accessed.

9. The method of claim 5, wherein the memory module information file is accessed by one of a group comprising of an operating system, an application manager, and a BIOS.

10. The method of claim 5, wherein accessing the memory module information file includes using at least one of a model number and a manufacturer of the memory unit accessed in the SPD.

11. The method of claim 10, further including, prior to storing the subunit of the memory module information file in the register of the memory controller, parsing the memory module information file into selected data and storing the selected data in a non-volatile memory area.

12. The method of claim 11, wherein the memory module information file supports a memory module from a group comprising of Dynamic Random Access Memory (DRAM), Synchronous Random Access Memory, and Flash memory.

13. A system comprising:
A central processing unit;
A memory unit; and
A first unit to access a first unit of data from a Serial Presence Detect (SPD) device of the memory unit, and the first unit to access, via the first unit of data, a second unit of data stored separately from the first unit of data.

14. The system of claim 13, wherein the second unit of data is to be accessed from one of a group comprising of a hard disk drive, a floppy disc, a CD-ROM, and a separate computer interconnected via a network.

15. The system of claim 14, wherein the second unit of data is a memory module information file.

16. The system of claim 15, wherein the first unit is to store at least a subunit of the memory module information file in a register of a memory controller, the subunit of the information file to be used to throttle memory cycles.

17. The system of claim 16, wherein the memory module information file includes information related to at least one of a group comprising of multiple speeds of operation for the memory unit, multiple operating frequencies of the memory unit, memory trace length information, and package type information.

18. The system of claim 17, wherein the second unit of data is to be accessed in response to an initial booting of a computer system.

19. The system of claim 17, wherein the second unit of data is to be accessed in response to a change in the memory controller configuration register.

20. The system of claim 17, wherein the second unit of data is to be accessed in response to an indication that the memory module information file has not previously been accessed.

21. The system of claim 17, wherein the memory module information file is accessed by one of a group comprising of an operating system, an application manager, and a BIOS.

22. The system of claim 17, wherein the first unit is to access the memory module information file includes using at least one of a model number and a manufacturer of the memory unit accessed in the SPD.

23. The system of claim 21, wherein prior to storing the subunit of the memory module information file in the register of the memory controller, the first unit is to parse the memory module information file into selected data and storing the selected data in a non-volatile memory area.

24. The system of claim 22, wherein the memory module information file is to support a memory module from a group comprising of Dynamic Random Access Memory (DRAM), Synchronous Random Access Memory, and Flash memory.

25. A system comprising:
A central processing unit;
A memory unit;
A graphics controller; and
A first unit to access a first unit of data from a Serial Presence Detect (SPD) device of the memory unit, and the first unit to access, via the first unit of data, a second unit of data stored separately from the first unit of data.

26. The system of claim 25, wherein the second unit of data is to be accessed from one of a group comprising of a hard disk drive, a floppy disc, a CD-ROM, and a separate computer interconnected via a network.

27. The system of claim 26, wherein the second unit of data is a memory module information file.

28. The system of claim 27, wherein the first unit is to store at least a subunit of the memory module information file in a register of a memory controller, the subunit of the information file to be used to throttle memory cycles.

29. The system of claim 28, wherein the memory module information file includes information related to at least one of a group comprising of multiple speeds of operation for the memory unit, multiple operating frequencies of the memory unit, memory trace length information, and package type information.

30. The system of claim 29, wherein the second unit of data is to be accessed in response to an initial booting of a computer system.

31. The system of claim 29, wherein the second unit of data is to be accessed in response to a change in the memory controller configuration register.

32. The system of claim 29, wherein the second unit of data is to be accessed in response to an indication that the memory module information file has not previously been accessed.

33. A machine-readable medium having stored thereon a set of instructions, which when executed by a processor, perform method comprising:
Accessing a first unit of data from a Serial Presence Detect (SPD) device of a memory unit; and
Accessing, via the first unit of data, a second unit of data stored separately from the first unit of data.

34. The machine-readable medium of claim 33, wherein the second unit of data is accessed from one of a group comprising of a hard disk drive, a floppy disc, a CD-ROM, and a separate computer interconnected via a network.

35. The machine-readable medium of claim 34, wherein the second unit of data is a memory module information file.

36. The machine-readable medium of claim 35, wherein the method further includes storing at least a subunit of the memory module information file in a register of a memory controller, the subunit of the information file to be used to throttle memory cycles.

37. The machine-readable medium of claim 36, wherein the memory module information file includes information related to at least one of a group comprising of multiple speeds of operation for the memory unit, multiple operating frequencies of the memory unit, memory trace length information, and package type information.

38. The machine-readable medium of claim 37, wherein the second unit of data is accessed in response to an initial booting of a computer system.

39. The machine-readable medium of claim 37, wherein the second unit of data is accessed in response to a change in the memory controller configuration register.

40. The machine-readable medium of claim 37, wherein the second unit of data is accessed in response to an indication that the memory module information file has not previously been accessed.

41. The machine-readable medium of claim 37, wherein the memory module information file is accessed by one of a group comprising of an operating system, an application manager, and a BIOS.

42. The machine-readable medium of claim 37, wherein accessing the memory module information file includes using at least one of a model number and a manufacturer of the memory unit accessed in the SPD.
